(19) United States
(12) Patent Application Publication
(10) Pub. No.: US 2017/0288108 A1
(43) Pub. Date: Oct. 5, 2017

(54) LIGHT-EMITTING DIODE DEVICE

(71) Applicant: OSRAM Opto Semiconductors GmbH, Regensburg (DE)

(72) Inventors: Michael Schumann, Neu-Ulm (DE); Tobias Gebuhr, Regensburg (DE); David Racz, Regensburg (DE); Matthias Sperl, Mintraching (DE)

(21) Appl. No.: 15/507,767

(22) PCT Filed: Aug. 31, 2015
(86) PCT No.: PCT/EP2015/069861

§ 371 Date: Mar. 1, 2017

(30) Foreign Application Priority Data
Sep. 1, 2014 (DE) 10 2014 112 540.1

(51) Int. Cl. H01L 33/62; H01L 33/50; H05K 3/32; H01L 33/58; H05K 1/18; H01L 33/56; H01L 33/60

(52) U.S. Cl. CPC H01L 33/62; H01L 33/56; H01L 33/502; H01L 33/60; H01L 33/58; H05K 1/18; H05K 3/32; H01L 2933/0066; H01L 2933/005; H01L 2933/0041; H01L 2933/0058; H05K 2201/10106

(57) ABSTRACT

An optoelectronic device includes a printed circuit board, and a light source arranged on a surface of the printed circuit board, said light source comprising at least one luminous face formed by at least one light-emitting diode wherein the light-emitting diode is electrically connected to the printed circuit board, wherein the light-emitting diode is at least partly enclosed by molding by a potting compound.

### RELATED APPLICATIONS

The present application is a national stage entry according to 35 U.S.C. §371 of PCT application No.: PCT/EP2015/069861 filed on Aug. 31, 2015, which claims priority from German application No.: 10 2014 112 540.1 filed on Sep. 1, 2014, and is incorporated herein by reference in its entirety.

### TECHNICAL FIELD

Various embodiments relate to an optoelectronic device and to a method for producing an optoelectronic device.

### BACKGROUND

Optoelectronic devices including a light-emitting diode are known as such. In principle, here there is a need for a flexible package concept for improving a device design with regard to interconnectability (complex multi-chip modules, vertical soldering pad structures), device geometry and integration of optics.

The problem addressed by the present disclosure can therefore be considered that of providing an optoelectronic device which enables an improved and flexible interconnectability and an improved integration of optics.

The problem addressed by the present disclosure can also be considered that of specifying a corresponding method for producing an optoelectronic device.

### SUMMARY

These problems are solved by the respective subject matter of the independent claims. Advantageous configurations of the present disclosure are the subject matter of respectively dependent subclaims.

According to one aspect, an optoelectronic device is provided, including:
a printed circuit board,
a light source (or else a plurality thereof) arranged on a surface of the printed circuit board,
said light source including at least one luminous face formed by at least one light-emitting diode wherein
the light-emitting diode is electrically connected to the printed circuit board, wherein
the light-emitting diode is at least partly enclosed by molding (in particular completely enclosed by molding) by a potting compound.

In accordance with a further aspect, a method for producing an optoelectronic device is provided, including the following steps:
providing a printed circuit board,
arranging a light source onto a surface of the printed circuit board, wherein
the light source includes at least one luminous face formed by at least one light-emitting diode,
electrically connecting the light-emitting diode to the printed circuit board,
at least partly enclosing (in particular completely enclosing) the light-emitting diode by molding by a potting compound.

The present disclosure thus includes, in particular, the concept of advantageously combining with one another firstly printed circuit board technology and secondly molding that is known from QFN technology. In this case, “QFN” stands for “quad flat no leads package”. As a result, the advantages afforded by both technologies can advantageously be combined with one another. The optoelectronic device thus has advantages of the two technologies. This advantageously makes it possible, for example, on account of providing the electrical printed circuit board, to bring about a flexible electrical contacting for the light-emitting diode. That is to say, for example, that a high flexibility with regard to an interconnectability of the light-emitting diode is provided. Here the printed circuit board affords the technical advantage, in particular, that a multiplicity of electrical circuit layouts are possible for optimally electrically contacting the light-emitting diode. Moreover, a number of potentials for the diodes is furthermore advantageously not limited. In particular, this advantageously makes it possible to integrate further electronic devices, for example a protective diode or freewheeling diode and also a temperature sensor, in particular an NTC (negative temperature coefficient thermistor) sensor, or else other sensor system or analysis system components on the printed circuit board.

Molding in the sense of the present disclosure denotes transfer molding, in particular film assisted transfer molding. That is to say that molding is based on a transfer molding method, in particular a film assisted transfer molding method. This is in contrast to a traditional potting process, in which a homogeneous and planar surface cannot arise. In the meantime, in the case of transfer molding, in particular in the case of film assisted transfer molding, the electronic devices (diode, chips, NTC sensor, further electronic devices) and further components can be completely embedded. In this case, a defined and smooth surface advantageously arises. If sealing is effected for example by mans of the film on the chip surface, then the encapsulating material (the potting compound) is also at the same height level. This is provided in this way according to one embodiment.

The fact that the light-emitting diode is at least partly enclosed by transfer molding or enclosed by molding by the potting compound, which can also be referred to as molding compound, for example, affords the technical advantage, in particular, that good protection of the light-emitting diode against external influences is provided. In particular, the areas that are potted by the potting compound need not have an anticorrosion layer, since said areas are encapsulated by means of the potting compound. This analogously also applies to a soldering resist, which thus no longer need be applied on the areas that are potted by transfer molding or enclosed by molding by means of the potting compound.

The potting compound also advantageously makes it possible to conceal specific structures or components on the printed circuit board, that is to say make them virtually invisible. The components that are enclosed by molding or embedded are concealed from a user who looks at the device from outside. This is expedient particularly with regard to a visually attractive design. In particular, a homogeneous visual impression of the device is brought about as a result. In particular, a homogeneous color impression of the device is brought about. The color corresponding to the color impression results, in particular, from the color of the potting compound. That is to say therefore, in particular, that a specific color impression, for example a white color impression, for a user can be generated by means of a correspondingly chosen potting compound.

Furthermore, a flexible device geometry, for example round or angular, is made possible. This is the case, in particular, because a printed circuit board can be manufactured, for example cut, in a tailored shape as desired. That is to say, in particular, that the printed circuit board can have flexible shapes, for example round or angular. During molding, the potting compound then adapts to this shape of the printed circuit board given appropriate selection of the molding tool or molding insert required for this purpose.

Furthermore, the potting compound makes it possible, in a simple manner, to produce further structures, for example a reflector structure or a cavity, which are formed from the potting compound. This is brought about, in particular, by the use of an appropriately formed mold for molding.

A printed circuit board in the sense of the present disclosure can be referred to, in particular, as a printed circuit card, circuit board or as a printed circuit. The printed circuit board is also referred to as a “PCB”. A printed circuit board in the sense of the present disclosure includes, in particular, an electrically insulating material, for example a dielectric. Conductive connections, the conductor tracks, are arranged on said electrically insulating material. In particular, the conductive connections adhere to the printed circuit board. By way of example, a fiber-reinforced plastic is provided as electrically insulating material. In particular, the conductor tracks are etched from a thin layer of copper. That is to say therefore, in particular, that a printed circuit board in the sense of the present disclosure includes a carrier composed of an electrically insulating material, wherein one or a plurality of conductor tracks formed from copper, for example, are arranged on the carrier. In particular, the printed circuit board includes one or a plurality of plated through holes, so-called vias. The light-emitting diode may be electrically connected to one or a plurality of conductor tracks and/or to one or a plurality of vias.

In another embodiment it is provided that the light-emitting diode is completely embedded or enclosed by molding.

According to one embodiment it is provided that the light-emitting diode is enclosed by molding to an extent such that exclusively the luminous face is no longer enclosed by molding, that is to say remains free. That is to say therefore, in particular, that, in this embodiment, the luminous face remains or is formed free of potting compound. That is to say, in particular, that only the light-emitting face, that is to say the luminous face, is visible in the molded state.

In a further embodiment it is provided that the printed circuit board includes an anchoring structure for anchoring the potting compound on the printed circuit board, such that the potting compound is anchored on the printed circuit board by the anchoring structure. This affords the technical advantage, in particular, that the potting compound or molding compound is held mechanically stably and robustly on the printed circuit board.

In another embodiment it is provided that the anchoring structure includes at least one cutout in which potting compound is received. This affords the technical advantage, in particular, that an even stabler mechanical anchoring is brought about.

In another embodiment it is provided that the cut out is a through hole. That is to say therefore, in particular, that the printed circuit board includes a through hole. This affords the technical advantage, in particular, that an even stabler anchoring of the potting compound on the printed circuit board is brought about.

In another embodiment it is provided that a plurality of cutouts, advantageously a plurality of through holes, are provided. The plurality of cutouts, in particular the plurality of through holes, are formed in particular identically or advantageously differently.

According to a further embodiment it is provided that the anchoring structure includes two opposite edges of the surface which are potted by means of the potting compound. This affords the technical advantage, in particular, that structures of the printed circuit board that are already present are efficiently used as an anchoring structure: here the two opposite edges. Said two opposite edges thus act as an anchor for the potting compound. In particular, as a result, advantageously it is possible to dispense with further anchoring structures; by way of example, it is possible to dispense with a cutout, advantageously a through hole. Consequently, this advantageously obviates the need to additionally include space for such a cutout, for example a through hole, when planning the layout of the printed circuit board. The printed circuit board can thus advantageously be made smaller.

According to another embodiment it is provided that the potting compound includes a mounting face for mounting of a component, said mounting face being formed parallel to the surface. This affords the technical advantage, in particular, that one or a plurality of components can be arranged or mounted onto the potting compound, that is to say more precisely onto the mounting face. Consequently, even further components can be mounted onto the device after molding.

According to another embodiment it is provided that the surface includes a potting-compound-free-section (or a plurality of potting-compound-free-sections) for mounting of a component. This affords the technical advantage, in particular, that even after molding it is possible to mount or arrange components (the singular is intended also always to be inferred) onto the surface of the printed circuit board. Consequently, it is thus advantageously possible subsequently, that is to say after molding, to arrange components onto the printed circuit board.

According to one embodiment it is provided that the component is a lens mount or a reflector. In particular, the component is a lens. In particular, a plurality of components are arranged or mounted onto the mounting face and/or onto the potting-compound-free-section. The plurality of components may be formed identically or, in particular, differently.

According to one embodiment it is provided that the component is arranged or mounted both on the mounting face and on the potting-compound-free-section. That is to say therefore, in particular, that the component itself has a mounting face that corresponds to the geometry and structure of the potting-compound-free-section and of the mounting face, such that the component can be placed or mounted or arranged by its mounting face onto the mounting face of the potting compound and onto the potting-compound-free-section of the surface of the printed circuit board.

In a further embodiment it is provided that as component a lens mount is arranged on the mounting face or respectively the potting-compound-free-section. This affords the technical advantage, in particular, that a lens can be mounted in a simple manner. This then advantageously makes it possible for light emitted by the light-emitting diode to be optically imaged by the lens.

In a further embodiment it is provided that the potting compound includes a reflector section for reflecting light emitted by the diode. That is to say therefore, in particular, that a part of the potting compound forms a reflector. Thus an additional reflector need not necessarily be placed onto the potting compound for the purpose of reflecting the light emitted by the light-emitting diode. Said reflector section is advantageously formed during molding on account of an appropriately shaped mold. A reflector section or a reflector in the sense of the present disclosure is configured, in particular, to reflect the light emitted by means of the light-emitting diode away from the luminous face.

According to a further embodiment it is provided that an anchoring structure for anchoring the potting compound on the printed circuit board is formed on the printed circuit board before molding, such that during molding the potting compound is anchored onto the printed circuit board by the anchoring structure.

In accordance with a further embodiment it is provided that the anchoring structure includes at least one cutout which is formed on the printed circuit board, such that potting compound is received into the cutout during molding.

In a further embodiment it is provided that a mounting face for mounting of a component, said mounting face being parallel to the surface, is formed by means of the potting compound during molding.

According to a further embodiment it is provided that during molding a section of the surface is kept free of potting compound, such that after molding the surface includes a potting-compound-free-section for mounting of a component.

According to another embodiment it is provided that as component a lens mount is arranged onto the mounting face or respectively onto the potting-compound-free-section.

In accordance with another embodiment it is provided that a reflector section for reflecting light emitted by means of the diode is formed by means of the potting compound during molding.

In one embodiment, the diode is formed as a light-emitting diode chip (LED chip).

In a further embodiment, a plurality of diodes are formed per luminous face.

According to another embodiment, a plurality of luminous faces are provided.

In accordance with a further embodiment, a plurality of light sources are provided.

In one embodiment, a conversion layer is arranged on the luminous face of the diode. A surface facing away from the luminous face of the diode is likewise luminous during the operation of the diode on account of the conversion; therefore, this surface of the conversion layer can also be referred to as a luminous face. The conversion layer includes a phosphor, for example.

In one embodiment, the potting compound includes an epoxy resin and/or a silicone. In particular, the potting compound is white. Other colors, too, may advantageously be provided; for example: red, yellow, green, blue, orange, purple, grey or black.

Embodiments regarding the method analogously arise from embodiments regarding the device, and vice versa. That is to say that explanations, technical advantages and features of the device analogously also apply to the method, and vice versa.

### BRIEF DESCRIPTION OF THE DRAWINGS

The above-described properties, features and advantages of the present disclosure and the way in which they are achieved will become clearer and more clearly understood in association with the following description of the embodiments which are explained in greater detail in association with the drawings.

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIGS. 1 to 3 in each case show a different point in time in a method for producing an optoelectronic device,

FIGS. 4 to 9 in each case show a point in time in a process for producing a printed circuit board,

FIG. 10 shows an optoelectronic device,

FIGS. 11 to 13 in each case show a point in time in a process for producing a printed circuit board,

FIG. 14 shows a further optoelectronic device,

FIG. 15 shows a mold apparatus in a schematic view,

FIG. 16 shows a plan view of a printed circuit board including a plurality of light sources before molding,

FIG. 17 shows a lateral sectional view of the printed circuit board in accordance with FIG. 16,

FIG. 18 shows a plan view of the printed circuit board in accordance with FIG. 16 after molding,

FIG. 19 shows a lateral sectional view of the printed circuit board after molding in accordance with FIG. 18,

FIGS. 20 to 23 respectively show the same views in accordance with FIGS. 16 to 19 of a printed circuit board including a plurality of light sources in another embodiment,

FIG. 24 shows a plan view of a printed circuit board at a specific point in time during a method for producing an optoelectronic device,

FIG. 25 shows a lateral sectional view of the printed circuit board in accordance with FIG. 24,

FIG. 26 shows a plan view of the printed circuit board in accordance with FIG. 24 at a later point in time in the production method,

FIG. 27 shows a lateral sectional view of the printed circuit board in accordance with FIG. 26,

FIG. 28 shows a plan view of the printed circuit board in accordance with FIG. 26 at an even later point in time in the production method,

FIG. 29 shows a lateral sectional view of the printed circuit board in accordance with FIG. 28,

FIG. 30 shows a plan view of the printed circuit board in accordance with FIG. 28 at a further later point in time in the production method,

FIG. 31 shows a lateral sectional view of the printed circuit board in accordance with FIG. 30,

FIG. 32 shows a soldering pad such as is used for the printed circuit board in accordance with FIG. 24,

FIGS. 33 to 48 in each case show an optoelectronic device, and

FIG. 49 shows a flow diagram of a method for producing an optoelectronic device.

### DETAILED DESCRIPTION

Hereinafter, identical reference signs may be used for identical features. Furthermore, it is provided that not all features always have reference signs in the drawings. In particular, a simplified schematic illustration is provided, inter alia. This is intended to be for the sake of better clarity.

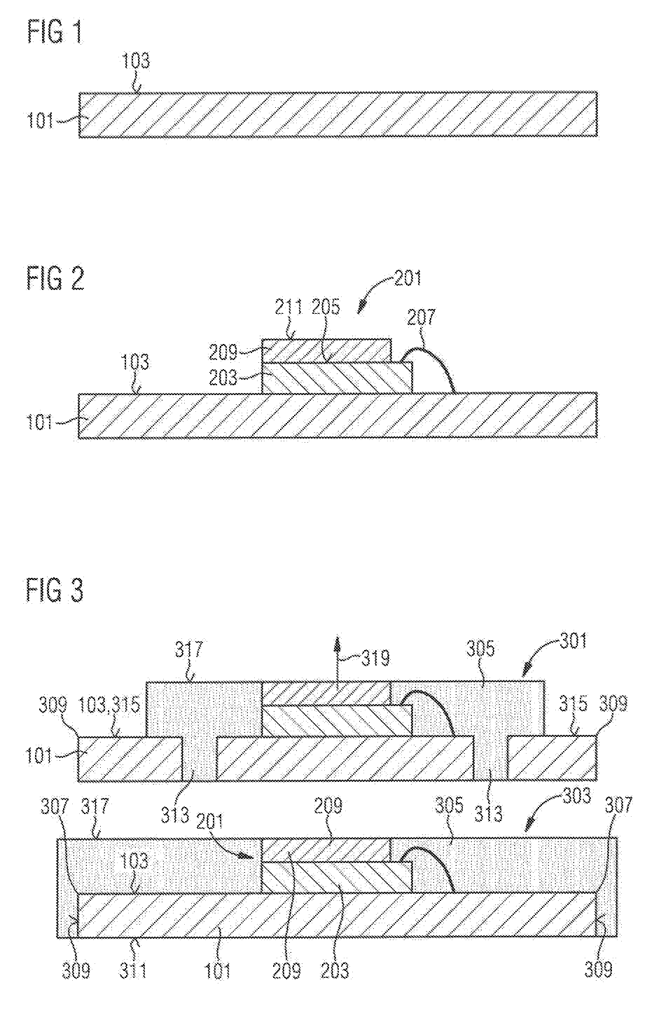

FIG. 1 shows a printed circuit board 101 having a surface 103. A light source including at least one or a plurality of light-emitting diodes is arranged or mounted onto said surface 103, as shown and explained below. The surface 103 may therefore be referred to, in particular, as a mounting face. In particular, the surface 103 may be referred to as an LED chip mounting face. This is the case, in particular, if an LED chip is mounted onto the surface 103.

The printed circuit board 101 is illustrated in a simplified manner. In this regard, the individual conductor tracks of the printed circuit board 101 are not shown. It is clear to the person skilled in the art, however, that a printed circuit board 101 usually includes one or a plurality of conductor tracks. The printed circuit board 101 is of monolayer or multilayer construction, for example. In particular, the printed circuit board 101 is based on “FR4” or “MCB”. “FR4” denotes a printed circuit board material. “MCB” stands for “Metal Core Board”.

FIG. 2 shows that a light source 201 is mounted or arranged on the printed circuit board 101, more precisely on the surface 103. The light source 201 includes an LED chip 203 including a luminous face 205. The LED chip 203 is electrically connected to conductor tracks of the printed circuit board 101 by means of one or a plurality of bonding wires 207. Analogously thereto, according to a further embodiment it is also possible to use chip technologies without wires (flip-chips). Here the electrical contacting takes place by means of two rear-side contacts from the chip. The precise manner of contacting is not illustrated in detail here. It is known to the person skilled in the art, however, how to electrically connect an LED chip 203 to conductor tracks of a printed circuit board by means of bonding wires 207.

A conversion layer 209 is arranged on the luminous face 205. Said conversion layer 209 converts the light emitted by the LED chip 203 into other light having a different wavelength. By way of example, the conversion layer 209 includes a phosphor. The reference sign 211 points to a surface of the conversion layer 209 which faces away from the luminous face 205 of the LED chip 203. In a plan view and in operation of the LED chip 203, the surface 211 is then also luminous of course. Said surface may therefore likewise be referred to as a luminous face.

FIG. 3 shows two optoelectronic devices 301 and 303 based on the arrangement shown in FIG. 2, wherein the arrangement shown in FIG. 2 was processed further, wherein here in particular the LED chip 203 was embedded or enclosed by molding.

In this regard, in accordance with the device 301 it is provided that two (or if necessary also a plurality of) through holes 313 were formed in the printed circuit board 101. Said through holes 313 receive potting compound 305 during molding. Said through holes 313 bring about an anchoring of the potting compound 305 that has at least partly enclosed by molding the LED chip 203 with the conversion layer 209 thereof and also the bonding wire or the bonding wires 207. That is to say that after molding only the surface 211 of the conversion layer 209 is exposed, that is to say is free of potting compound 305. Only this surface is still visible after molding. The further components, in particular the bonding wire or the bonding wires 207 and also the LED chip 203, are no longer visible after molding. The two through holes 313 form an anchoring structure.

As is furthermore shown in FIG. 3, the entire surface 103 of the printed circuit board 101 is not covered with potting compound or molding compound 305. Rather, there are potting-compound-free-sections 315 of the surface 103. The potting-compound-free-sections 315 can be used for example advantageously as a mounting face for a component, for example a lens mount or a reflector.

An emission direction of the light emitted by means of the LED chip 203 is identified by an arrow having the reference sign 319. This is also the case in further drawings, but not in all the drawings.

The device 303 does not have through holes 313 like the device 301. Rather, here two opposite edges 307 of the surface 103 form an anchoring structure for the potting compound 305. The two edges 307 are molded by the potting compound 305. In this case, the potting compound 305 furthermore covers lateral surfaces 309 that are formed perpendicularly to the surface 103 and adjacently to the respective edges 307. In the device 303, therefore, the potting compound 305 covers the surface 103 completely apart from the locations already occupied by the LED chip 103 and by the contact area of the bonding wires 207 on the surface 103.

The reference sign 311 points at a surface which, relative to the surface 103, that is to say the mounting surface for an LED chip, is situated opposite (that is to say the rear side of the printed circuit board 101). In an embodiment that is not shown, it may be provided that the potting compound 305 also furthermore at least partly covers the surface 311. That is to say that here the potting compound 305 reaches as it were under the printed circuit board 101 and can thus bring about an even better anchoring of the potting compound 305 on the printed circuit board 101.

In both embodiments, that is to say both in the device 301 and in the device 303, the potting compound 305 has a mounting face 317 formed parallel to the surface 103. In particular, said mounting face 317 is flush with the surface 211 of the conversion layer 209. A further component, for example a reflector or a lens mount, can advantageously be arranged on the mounting face 317.

To summarize, FIGS. 1 to 3 show the concept according to the present disclosure in a general illustration: the concept of providing a printed circuit board on which an LED chip is arranged, wherein said LED chip is then at least partly embedded or enclosed by molding by means of potting compound. In particular, it is provided that all devices and components arranged on the printed circuit board, more precisely on the surface 103, are enclosed by molding by the potting compound 305, such that only the surface 211 of the conversion layer 209 remains visible.

The potting compound 305 includes an epoxy resin or a silicone, for example.

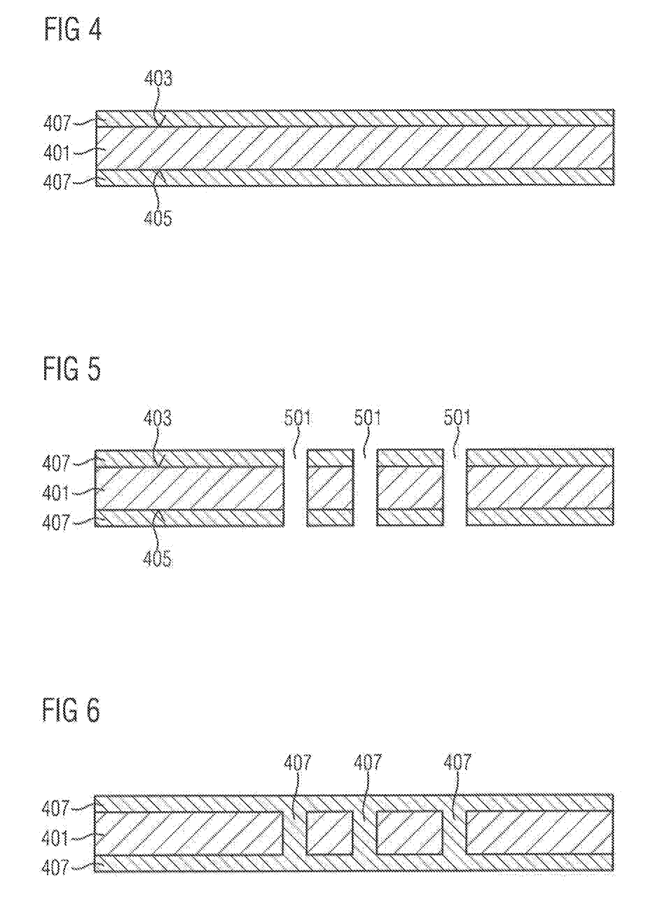

FIGS. 4 to 9 show different points in time during the production of a printed circuit board 101. In this regard, in accordance with FIG. 4, a dielectric 401 is provided, wherein a metal layer 407, for example including copper, is arranged or applied on opposite surfaces 403 and 405 of the dielectric 401. In accordance with FIG. 5, through holes 501 are formed through the dielectric 401 with the applied metal layers 407. The through holes 501 can for example be drilled, milled or formed by laser removal. In accordance with FIG. 6, coating then takes place, such that a metal layer 407 forms in the through holes 501. The coating may include electroplating, for example. In particular, the coating includes forming a “PTH”. “PTH” stands for “Plated through hole”, that is to say an electrically conductive via.

In accordance with FIG. 7, a structuring, for example by means of lithographic methods, of the arrangement in accordance with FIG. 6 takes place. That is to say that the electrical layout is formed in the step of structuring. That is to say therefore, in particular, that here in particular the individual conductor tracks of the printed circuit board 101 are formed.

FIG. 8 shows that the printed circuit board 101 structured in this way is also coated by means of a layer 801. The layer 801 is a metallization layer that is formed on the metal layer 407, for example on the copper layer. The layer 801 constitutes a so-called “Finish Plating”. The layer 801 includes NiPdAu, for example. The layer 801 may therefore be referred to as a metallization layer.

In accordance with FIG. 9, two through holes 313 are formed which run through the dielectric 401 and the metal layers 407. Said through holes 313 serve as an anchoring structure for the potting compound 305. FIG. 3 already shows this in a simplified illustration in accordance with the device 301. The individual metal layers were not shown in the illustration in accordance with FIG. 3. That is to say that the more detailed illustration of a printed circuit board 101 as shown in FIG. 9 corresponds to the printed circuit board 101 of the device 301 in accordance with FIG. 3.

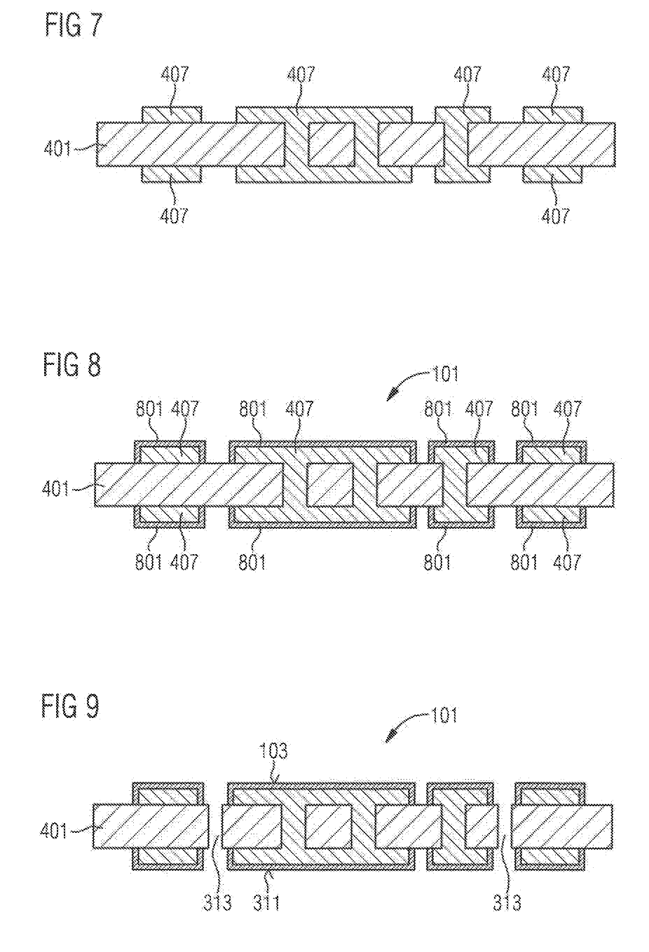

FIG. 10 shows the device 301 with the printed circuit board 101 shown in greater detail in accordance with FIG. 9 with a reflector 1001, which is arranged both on the potting-compound-free-sections 315 and on the mounting face 317. The reflector 1001 is then configured correspondingly. That is to say therefore, in particular, that said reflector has a structure adapted to the geometry and structure of the sections 315 and mounting face 317. The reflector 1001 is formed separately relative to the potting compound 309.

The reflector 1001 furthermore has reflector walls 1003 which are arranged opposite one another and run toward the surface 211 of the conversion layer 209 in a funnel-shaped fashion.

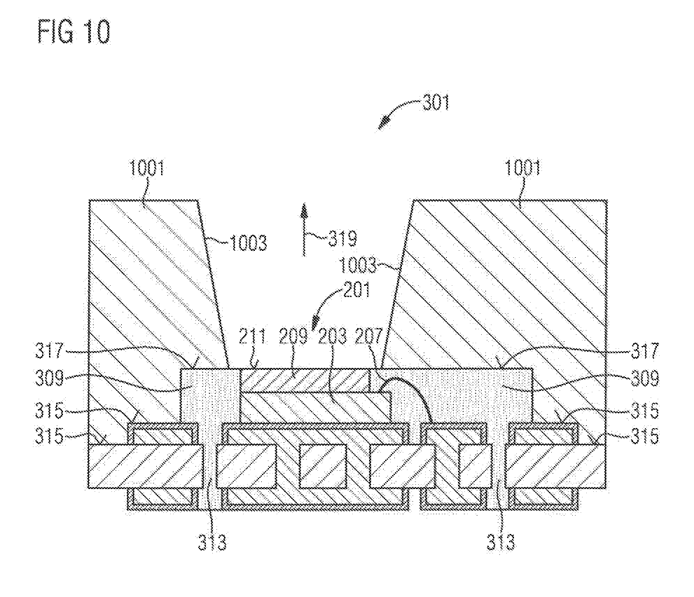

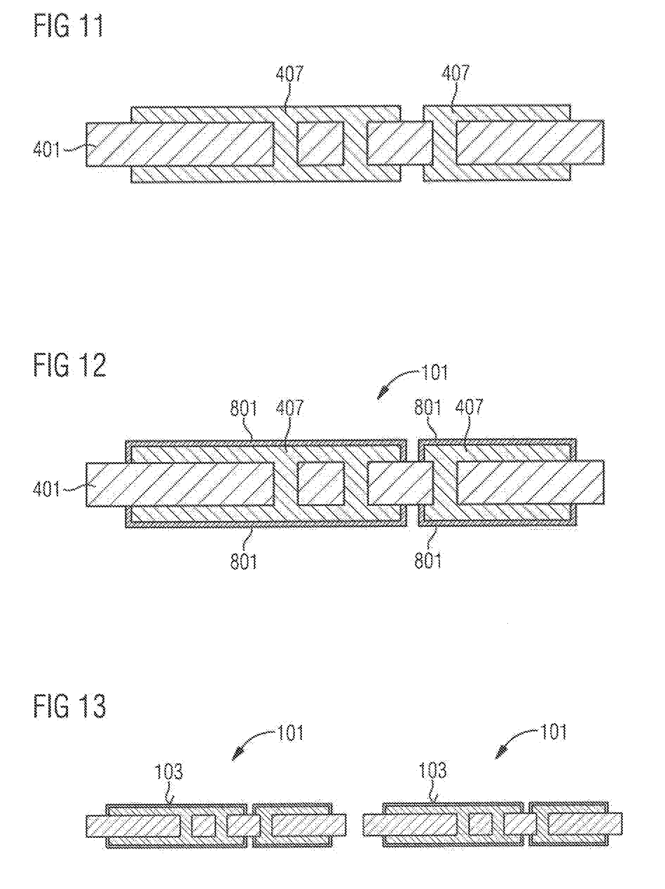

FIGS. 11 to 13 show points in time in a production method for a further printed circuit board 101. Production steps in accordance with FIGS. 4 to 6 are likewise provided here, but are not shown again. A structuring of the dielectric 401 took place in FIG. 7. A structuring, for example by means of a lithographic method, is analogously provided in FIG. 11, wherein a different structuring in comparison with FIG. 7 is chosen here. The specific structuring depends in particular on the desired circuit layout. In FIG. 12, the metallization layer 801 is applied to the metal layers 407. FIG. 13 shows the printed circuit board 101 including a plurality of such structured regions as shown in FIG. 12. That is to say therefore that on the printed circuit board 101 in accordance with FIG. 13 a respective light source can be arranged on these individual structured regions, wherein the individual structured regions can be singulated after molding. In this regard, by way of example, the printed circuit board 101 of the device 303 in accordance with FIG. 3 corresponds to the printed circuit board, as shown in FIG. 12, after singulation. The device enclosed by molding, with emplaced reflector 1001, is illustrated in greater detail in FIG. 14. In addition to the device 303 in accordance with FIG. 3, FIG. 14 shows that the potting compound 309 at least partly also covers the surface 311. That is to say that here the potting compound 305 reaches as it were around the printed circuit board. An even better anchoring of the potting compound 305 on the printed circuit board 101 is advantageously brought about as a result.

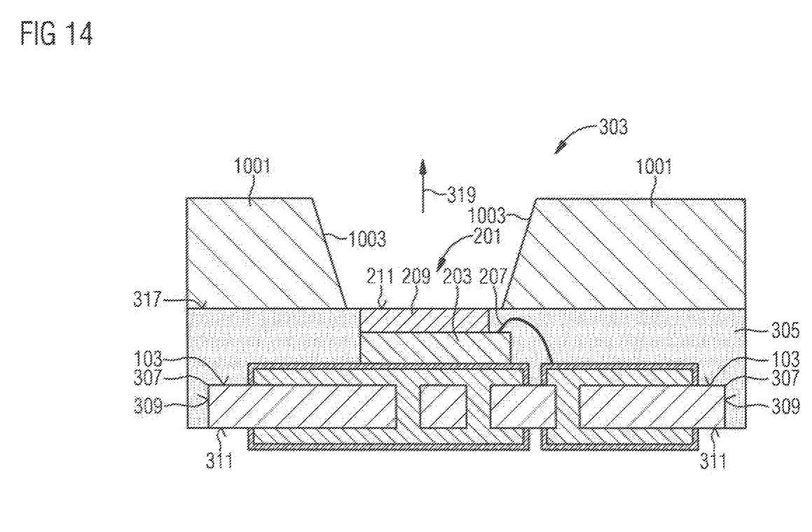

FIG. 15 shows a mold tool apparatus 1501 including two mold tools 1503 and 1505. The mold tool 1505 receives the printed circuit board 101 with LED chips 203 mounted thereon. The mold tool 1503 has an antistick film 1515 on a surface facing the printed circuit board 101. This advantageously prevents potting compound from sticking to the mold tool 1503 during molding.

The reference sign 1507 points at a lifting cylinder including a spring 1509, which lifting cylinder can introduce a molding or a potting compound 1511 into the space or into the cavity that is formed when the two mold tools 1503 and 1505 are placed one on top of the other and enclose the printed circuit board 101. A lifting direction of the lifting cylinder 1507 for introducing the potting compound 1511 is identified by an arrow having the reference sign 1513. In accordance with the chosen shape of the mold tools 1503 and 1505, precisely defined structures can be introduced into the potting compound 1511. By way of example, a reflector structure can be formed and/or advantageously flat and/or planar surfaces. This is shown in FIG. 39, for example, and also explained further there.

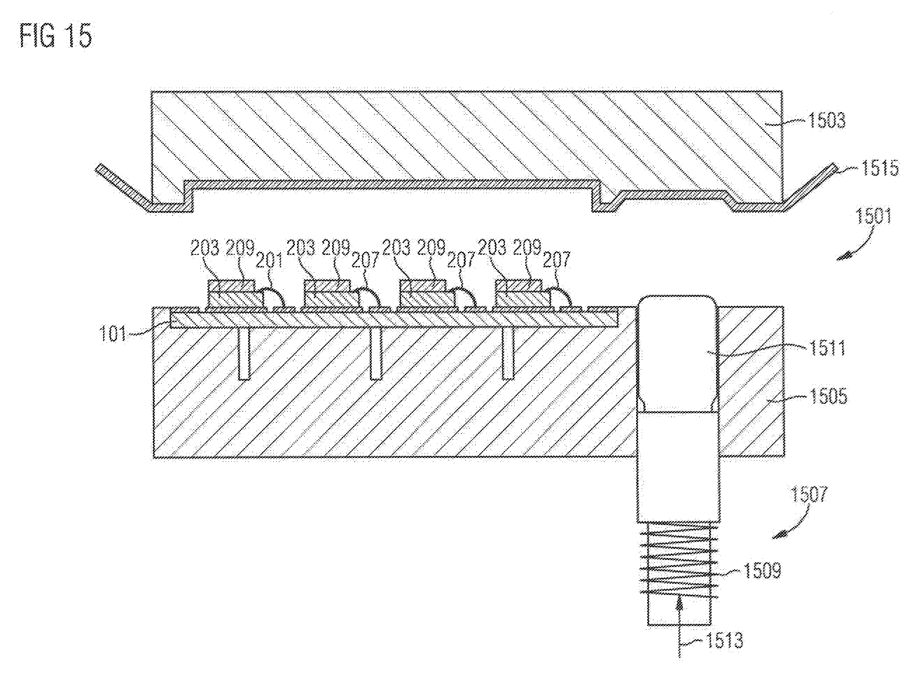

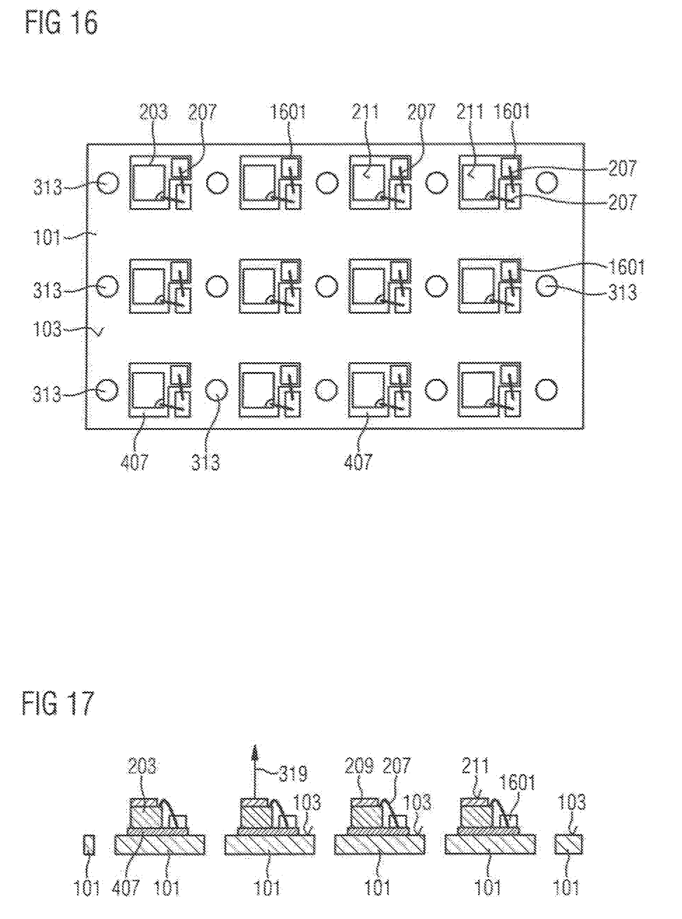

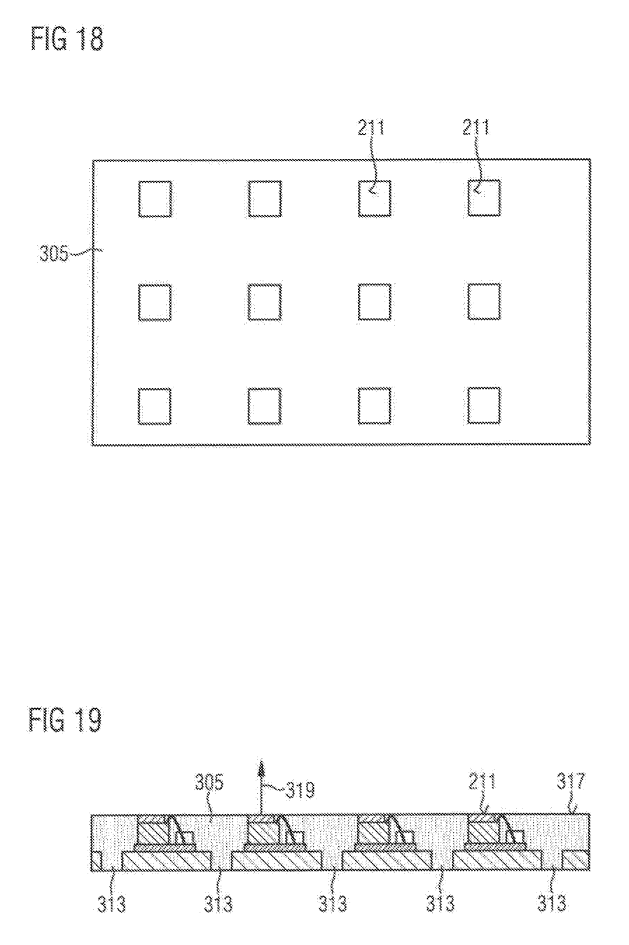

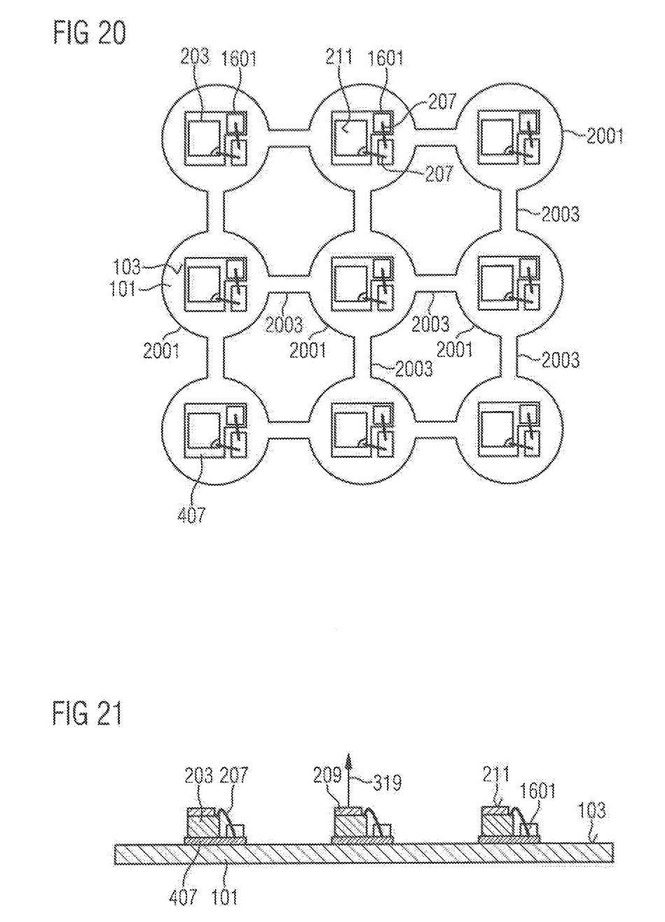

FIG. 16 shows a plan view of a printed circuit board 101 such as can be used for example in association with FIG. 15 and the corresponding mold tool apparatus 1501. A plurality of LED chips 203 are arranged on the printed circuit board 101, more precisely on the surface 103. Corresponding through holes through the printed circuit board 101 are identified by the reference sign 313. The reference sign 1601 points at protective diodes assigned to each LED chip 203. Said diodes advantageously bring about protection against electrostatic discharges. FIG. 17 shows a corresponding side view of the printed circuit board 101 in accordance with FIG. 16. The arrangement in accordance with FIG. 16 and respectively FIG. 17 has not yet been potted. FIGS. 18 and 19 here show corresponding views (FIG. 18: plan view, and FIG. 19: side view) after molding. After molding, as shown in FIG. 18, only the faces or surfaces 211 of the conversion layer 209 are visible. After molding, it may be advantageously provided that the plurality of LED chips 203 are singulated.

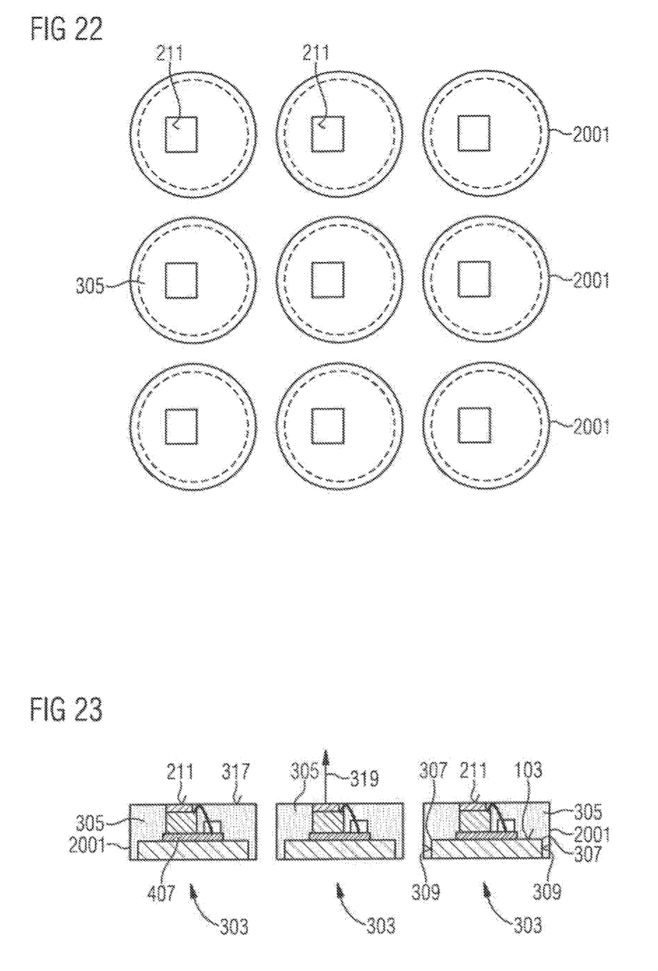

In a manner similar to FIGS. 16 to 19, FIGS. 20 to 23 show another exemplary embodiment in the corresponding views. FIG. 20 shows a plan view still before molding, and FIG. 21 shows a corresponding lateral sectional view. FIG. 22 shows a plan view after molding, and FIG. 23 shows a lateral sectional view of the arrangement in accordance with FIG. 22. The reference sign 2001 points at round sections of the printed circuit board 103, wherein an LED chip 203 with a respective protective diode 1601 is assigned to each round section 2001. Webs 2003 are provided between the individual round sections 2001, which webs are still formed from the printed circuit board material and connect the individual round sections 2001 to one another. Such an arrangement with webs 2003 and round sections 2001 is possible here. This is because no through holes for anchoring the molding compound or potting compound are provided in the arrangements shown in FIGS. 20 to 23. This is contrast to the arrangements shown in FIGS. 16 to 19. The latter have through holes 313 in which potting compound 305 is received in order to anchor the potting compound 305 on the printed circuit board 101.

The opposite edges of the surface which is embedded by the molding compound 305 are provided as anchoring in the embodiment in accordance with FIGS. 20 to 23.

Both in the case of the arrangement in accordance with FIGS. 16 to 19 and in the case of the arrangement in accordance with FIGS. 20 to 23, it is provided, for example, that after molding the individual LED chips which are then enclosed by molding are singulated.

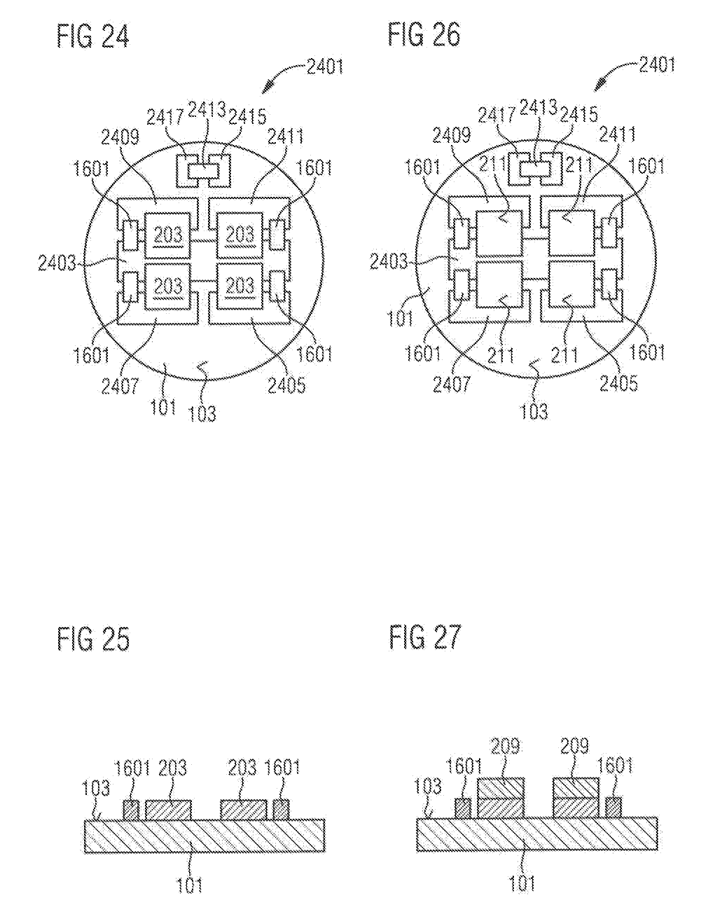

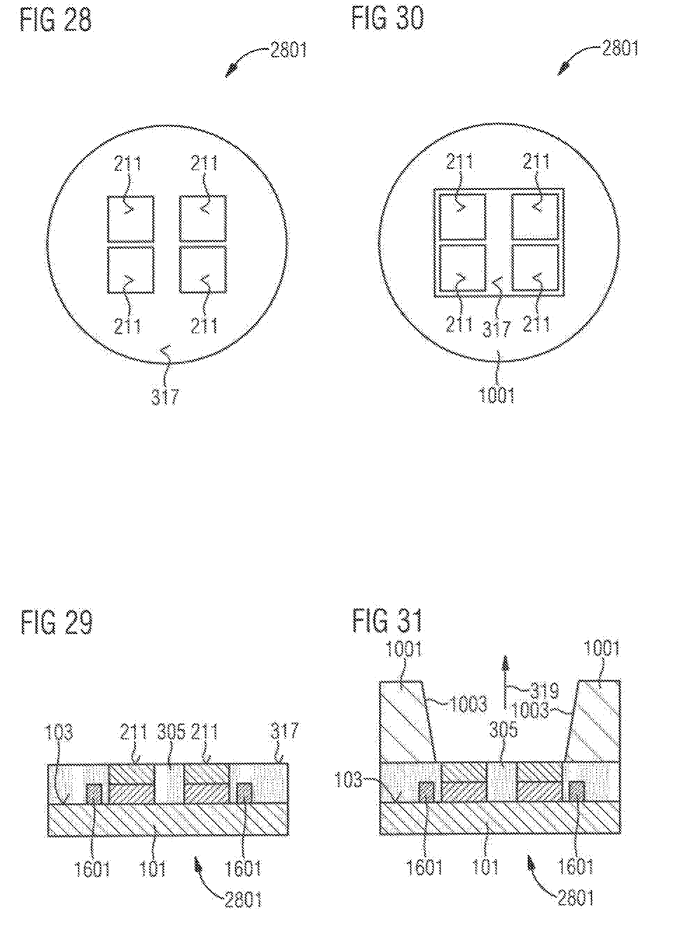

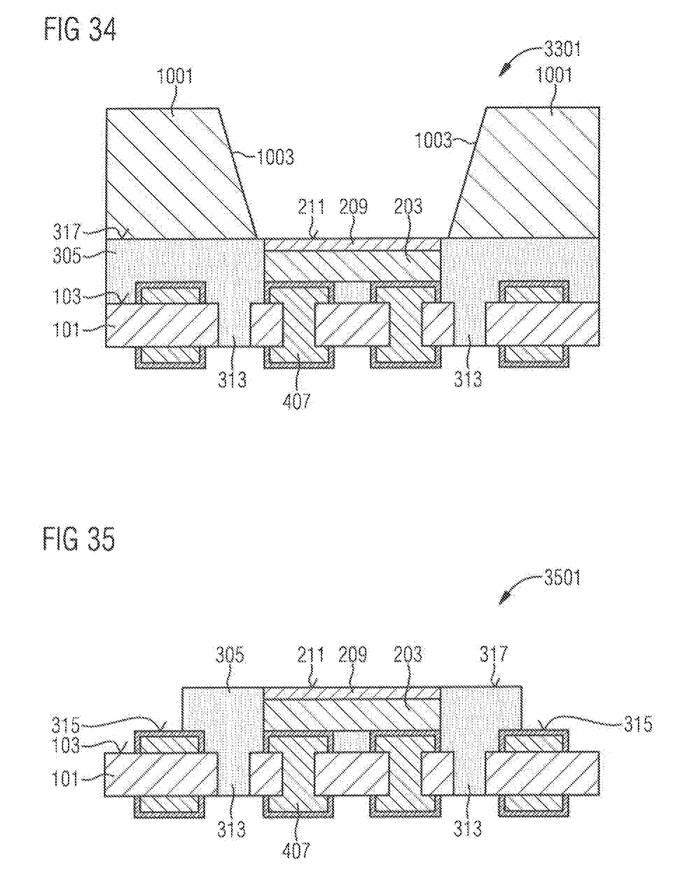

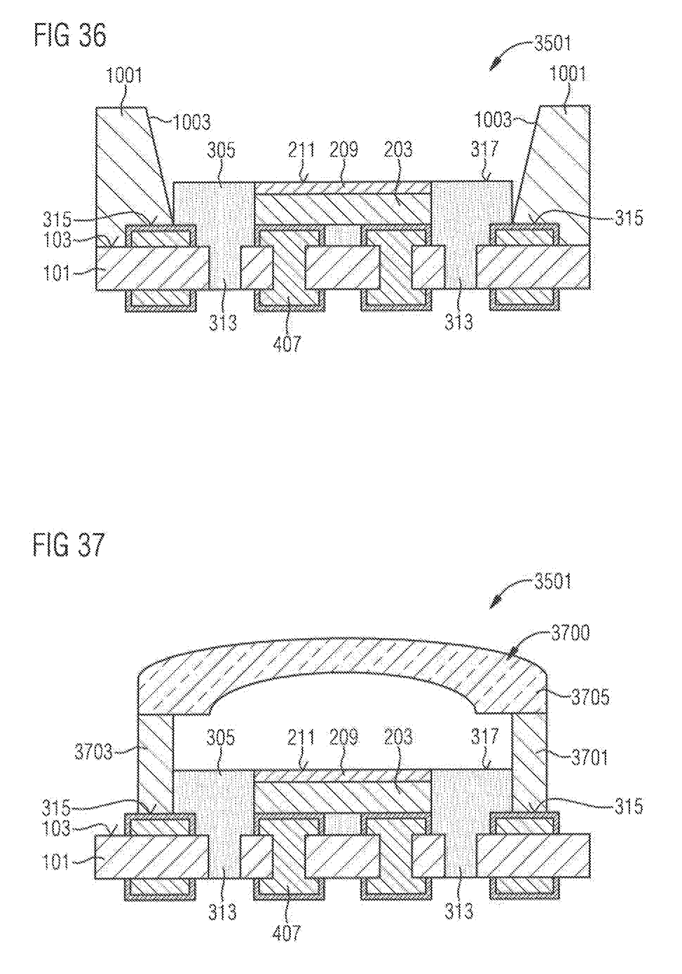

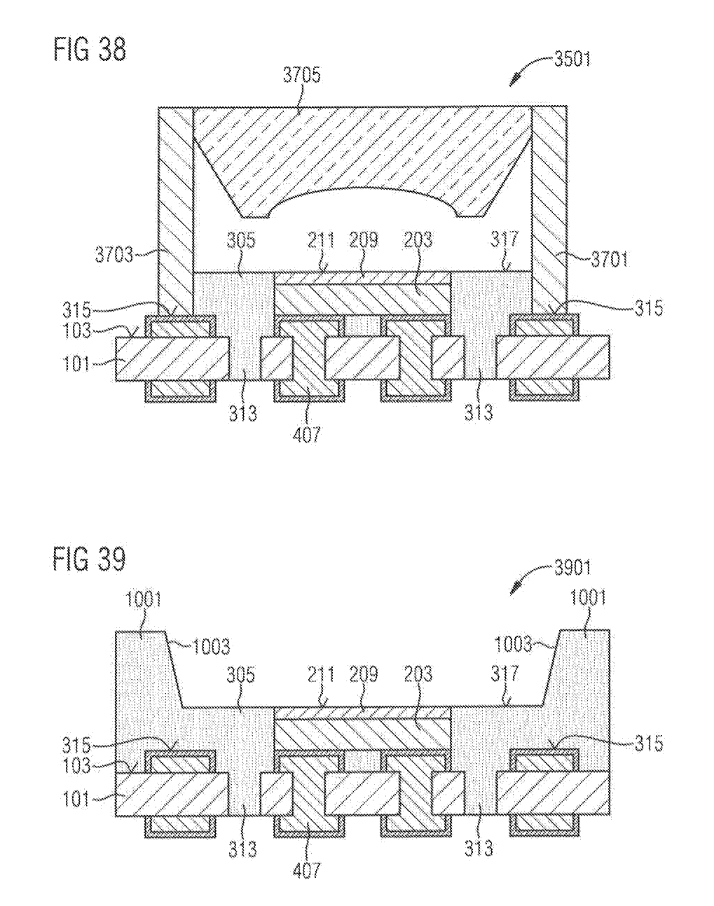

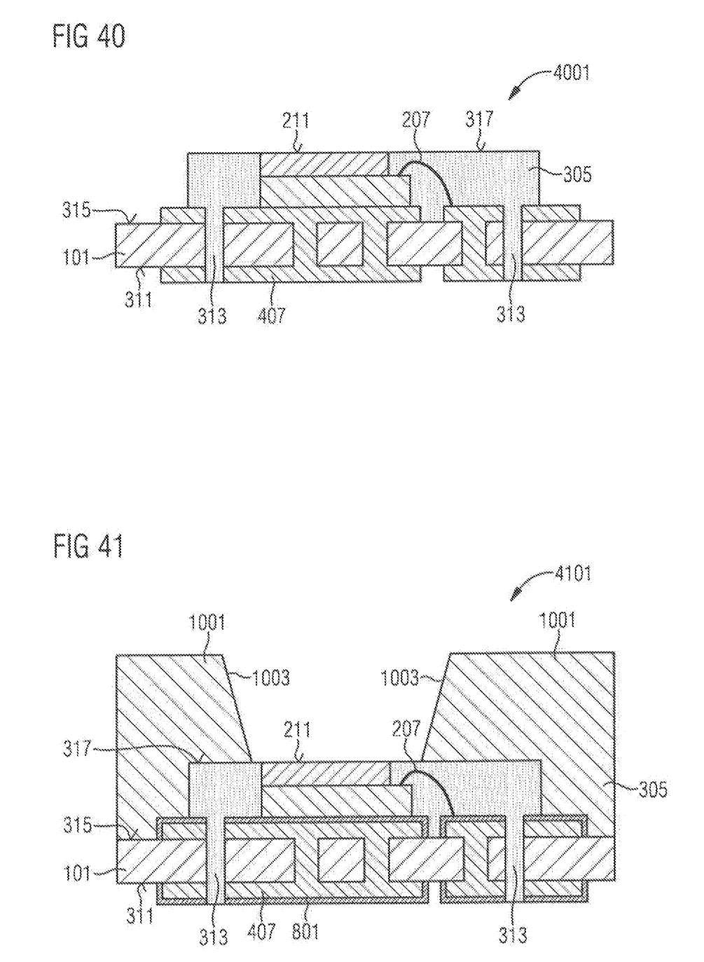

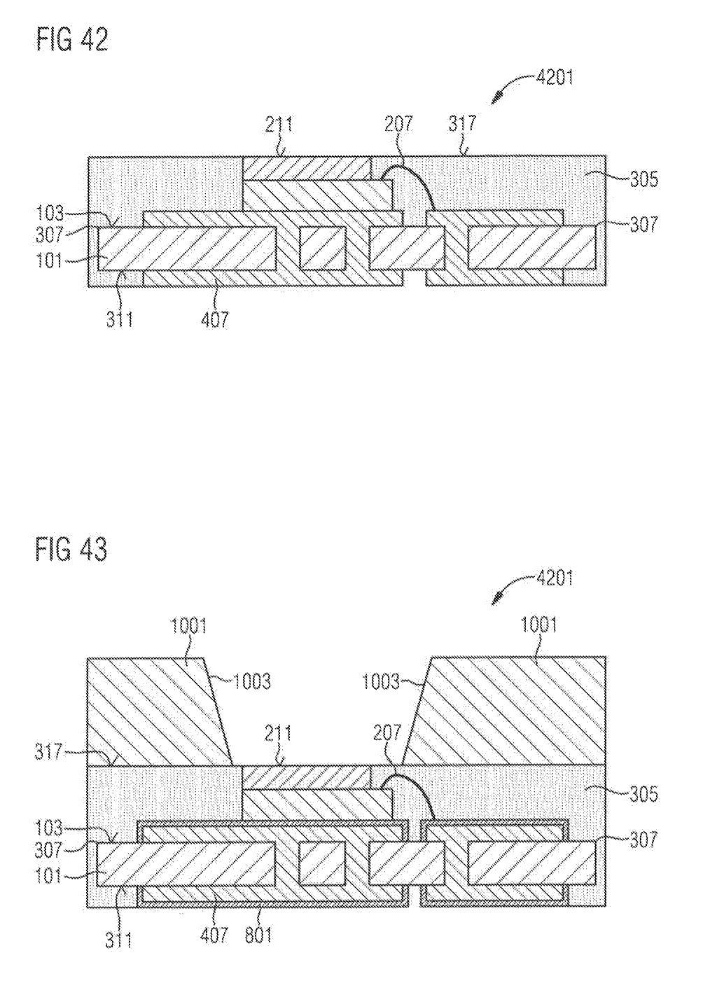

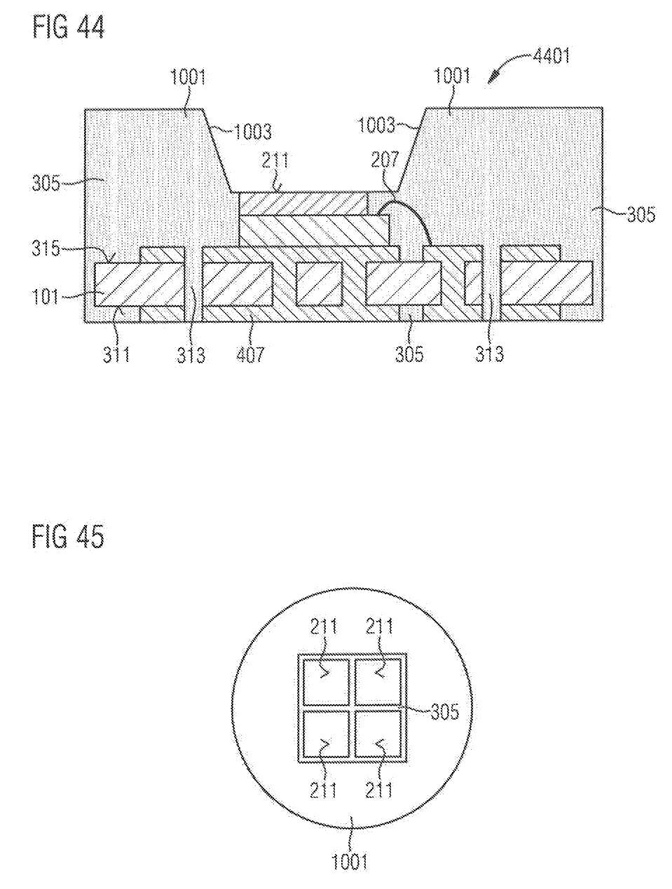

FIGS. 24, 26, 28, 30 in each case show a plan view of a device at different points in time during its production. FIGS. 25, 27, 29 and 31 show respectively corresponding lateral sectional views. Provision is made here for arranging four LED chips 203 on the printed circuit board, more precisely on a soldering pad 2401 (cf. FIG. 32). A respective conversion layer 209 is provided on the four LED chips 203, said conversion layers being formed differently, such that light having four different colors can be emitted. FIGS. 24, 25, 26, 27 show the device still before molding. In FIGS. 28 and 29, the device has been enclosed by molding. FIGS. 30 and 31 additionally show the reflector 1001 that is placed onto the mounting face 317.

FIG. 32 shows in greater detail the soldering pad 2401 that is used for an electrical contacting of the LED chips 203 with conductor tracks of the printed circuit board 101. In this regard, a central section 2403 is provided, which serves as a common cathode for the four LED chips 203. Sections 2405, 2407, 2409 and 2411 are provided separately therefrom and serve in each case for the contacting of the individual LED chips. Furthermore, regions 2415 and 2417 are provided which electrically contact an NTC sensor 2413.

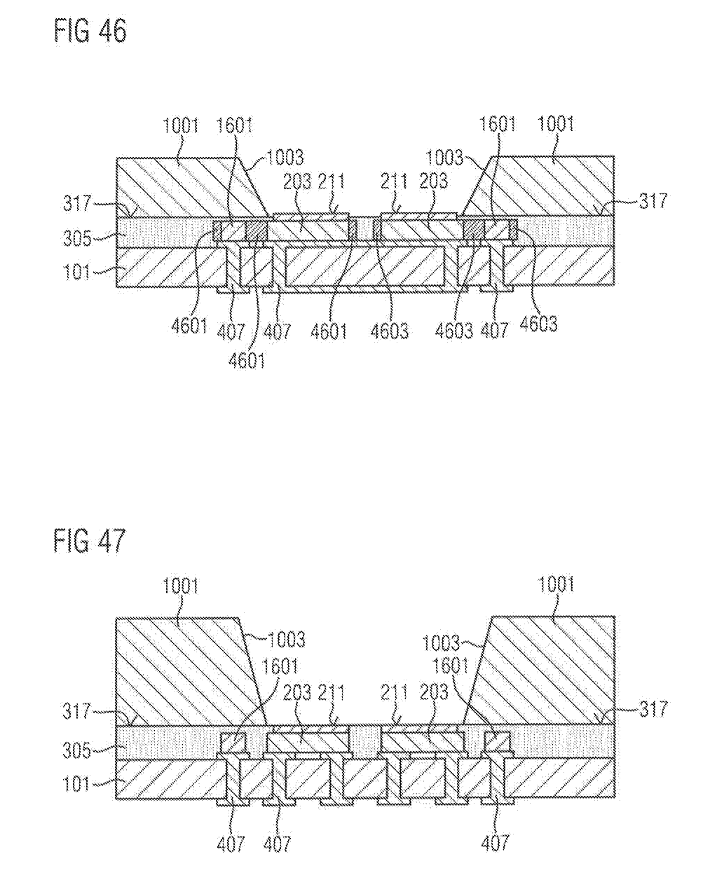

FIG. 33 shows a further device 3301, on which a reflector 1001 is placed in accordance with FIG. 34.

FIG. 35 shows another device 3501, on which components are also placed in accordance with FIGS. 36, 37 and 38. Said components are placed onto the potting-compound-free-sections 315. In this regard, a reflector 1001 is likewise placed onto said potting-compound-free-sections 315 (cf. FIG. 36). In accordance with FIG. 37, a lens mount 3700 is placed onto the potting-compound-free-sections 315, wherein the lens mount 3700 holds a lens 3705. The lens mount 3700 includes two columns 3701 and 3703, which are placed onto the potting-compound-free-sections 315 and are dimensioned in terms of their size or length such that they project beyond the surface 211 of the conversion layer 209. The lens 3705, which may be a Fresnel lens, for example, is then placed or arranged on these two columns 3701 and 3703.

In accordance with FIG. 38, a TIR lens 3705 is placed onto the two columns 3701 and 3703 of the lens mount 3700. “TIR” stands for “Total internal Reflection”.

FIG. 39 shows a further device 3901. Here the reflector 1001 with its reflector walls 1003 is formed from the molding compound 305. That is to say that the potting or molding compound 305 includes a reflector section 1001.

FIG. 40 shows an optoelectronic device 4001, wherein as anchoring structures through holes 313 are formed through the printed circuit board 101. Furthermore, potting-free sections 315 are provided on the surface 103 of the printed circuit board. In accordance with FIG. 41, a reflector 1001 as a separate device is placed onto said potting-free sections 315 and onto the mounting face 317 of the potting compound 305.

FIG. 42 shows a further optoelectronic device 4201. Here the potting compound 305 in the molded state reaches around opposite edges 307 of the surface 103. Furthermore, the potting compound 305 covers the surface 311 of the printed circuit board 101. The opposite edges 307 here form an anchoring structure. The mounting face 317 runs flush with the surface 211 of the conversion layer 209. In accordance with FIG. 43, a reflector 1001 is placed onto said mounting face 317.

FIG. 44 shows a further optoelectronic device 4401, wherein here the reflector 1001 is formed from the molding compound 305 or potting compound 305.

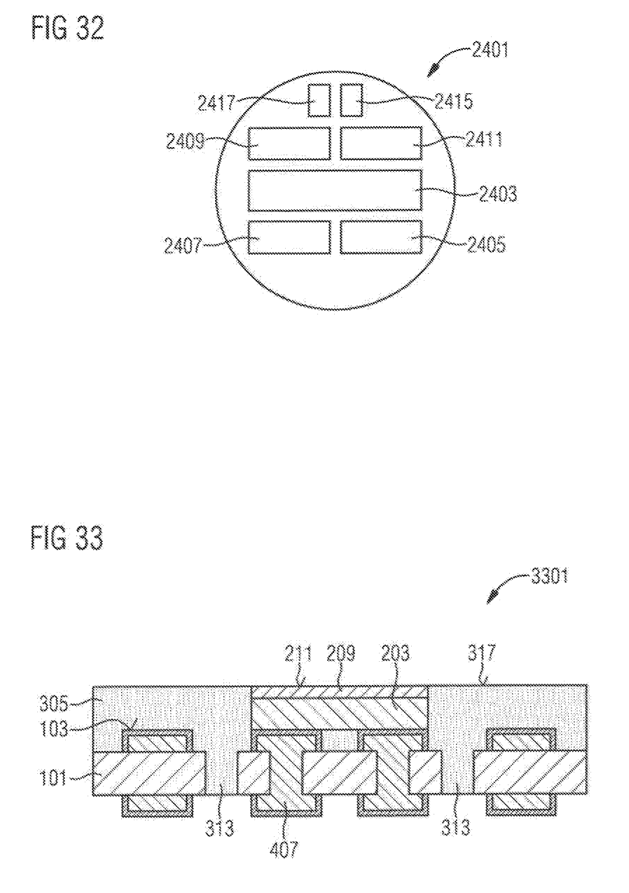

FIG. 45 shows a schematic plan view of a further optoelectronic device in accordance with FIGS. 46 to 48. In these devices there are four LED chips 203 with respectively different conversion layers 209, such that light having four different colors can be emitted (analogously to FIG. 26). The respective optoelectronic devices in FIGS. 46 to 48 differ, in particular, in that in FIGS. 46 and 47 the reflector 1001 is arranged or mounted on the mounting face 317 of the potting compound 305. In FIG. 48 the reflector 1001 is arranged on the potting-free sections 315. The individual electronic layouts of the printed circuit boards 1001 in FIGS. 46 to 48 also differ from one another.

In FIG. 46, the reference signs 4601 and 4603 point at frame structures that respectively frame the diodes 203 and the protective diode 1601. In this case, a so-called “Chip in a Frame Package” is involved. In this case, an ESD protection (that is to say the protection against electrostatic discharge) has already been integrated on an SMT (Surface Mounted Technology) independent package.

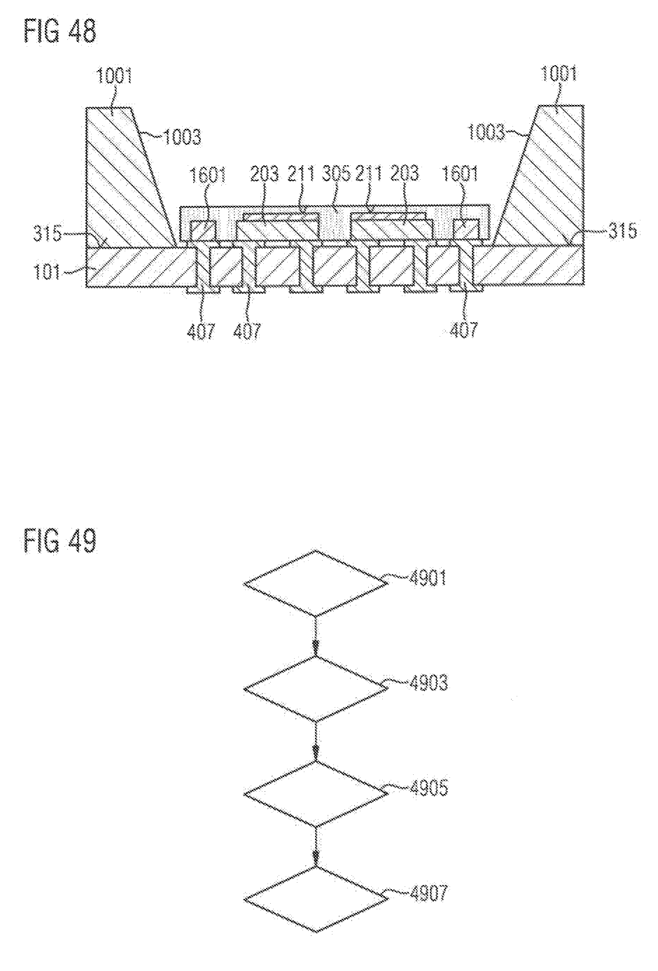

FIG. 49 shows a flow diagram of a method for producing an optoelectronic device, including the following steps:
providing (4901) a printed circuit board (101),
arranging (4903) a light source (201) onto a surface (103) of the printed circuit board (101), wherein
the light source (201) includes at least one luminous face (205) formed by at least one light-emitting diode (203),
electrically connecting (4905) the light-emitting diode (203) to the printed circuit board (101),
at least partly molding (4907) the light-emitting diode (203) by a potting compound (305).

The present disclosure thus encompasses the concept, in particular, of combining the strengths of printed circuit board technology with leadframe technology and concepts correspondingly based thereon, while at the same time minimizing the weaknesses. The following advantages can correspondingly be achieved in accordance with the different embodiments:
extremely flat and compact device dimensions possible,
integration of further electronic components (ESD, NTC, IC, sensors, etc.) possible
Industrial Design: concealment of components very simple
homogeneous color impression of the device (for example wire or ESD diode not visible)
only light-emitting area visible and limited to chip area (advantages in lens imaging, such as advantageously for example in the case of flash (flashlight) for mobile application or direct backlight)
multi-color module: no color crosstalk of the individual emitters, since laterally embedded
no emission of light laterally with respect to the device. This may be advantageous in flash or direct backlight in order to avoid “light contamination” of the camera or optical sensors.
Flexibility with regard to mounting faces for optical components directly at the PCB level (chip mounting face) or molded area (direct emission plane)
small distance between emission faces and reflector possible→minimization of optical losses (absorption)
use of soldering resist or corrosion-resistant platings in the case of a PCB not necessary in order to avoid corrosion, since surfaces are completely encapsulated
flexible integration into target application possible, for example base design for cover penetration or flat package directly below the lens or glass cover
direct production/integration of reflector structures or cavities possible
flexible device geometry (round or angular) possible

The flexibility of the designs makes it possible to fulfill customer requests which previously could not be realized by the individual concepts.

Advantages of a PCB substrate (that is to say of a printed circuit board as substrate or carrier) are for example:
proven and known package technology
low costs
panel arrangement or individual package on the PCB strip
excellent thermal conductivity
high (design) flexibility: monolayer, multilayer, size and geometry, flexible circuits/electrical interconnections, concealed/hidden through contacts, design and position of the soldering pad adaptable (vertical connection or at top side and underside), use of different potentials/multichip packages, various precision-ground/refinement metallizations are possible; high number of components possible on the printed circuit board.
Appearance: various possibilities/colors, no open Cu
arrangement of optical components or additional optical devices (reflector, lenses, diaphragms, . . . ) on the substrate
simple, for example mobile (diaphragm) incorporation into the application
chip arrangement not limited: adhesive bonding, soldering, wire bonding
possibility of onboard soldering

Exemplary advantages of molding by molding compound after arranging and electrically connecting the diode:
flat and very compact packages, incorporation of different devices possible in a simple manner
industrial design: concealment of all devices (LED, electronic devices, wires . . . .) within the housing matrix
the region of spots (luminous area)/emission is visible only to a small extent (optimized for lens/optical devices)→direct BLU applications or flash emitters (“BLU” stands for “Back Light Unit”)
different colors: no crossover of different emitters
light-blocking side walls (no lateral emission through mobile diaphragm)
free/flexible construction region: arrangement of optical devices at the PCB level (metal) or at the construction level/housing material (light emission region)→small distance between reflector and emission region
costs: use of soldering resistance or anticorrosion coating not necessary (ageing effects not visible)
simple incorporation into target application (shaft design in mobile diaphragm or bringing flat package near to the lens)
incorporation of reflector structure or cavity structure

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic device, comprising:
a printed circuit board,
a light source arranged on a surface of the printed circuit board, the light source comprising at least one light-emitting diode electrically connected to the printed circuit board and forming at least one luminous face of the light source, and
a potting compound molded to at least partly enclose the light emitting diode.

2. The optoelectronic device as claimed in claim 1, wherein the printed circuit board comprises an anchoring structure for anchoring the potting compound on the printed circuit board, such that the potting compound is anchored on the printed circuit board by the anchoring structure.

3. The optoelectronic device as claimed in claim 2, wherein the anchoring structure comprises at least one cutout in which potting compound is received.

4. The optoelectronic device as claimed in claim 3, wherein the cutout is a through hole.

5. The optoelectronic device as claimed in claim 2, wherein the anchoring structure comprises two opposite edges of the surface which are enclosed by molding by the potting compound.

6. The optoelectronic device as claimed in claim 1, wherein the potting compound comprises a mounting face for mounting of a component, wherein the mounting face is formed parallel to the surface.

7. The optoelectronic device as claimed in claim 1, wherein the surface comprises a potting-compound-free-section for mounting of a component.

8. The optoelectronic device as claimed in claim 6, wherein as component a lens mount is arranged on the mounting face.

9. The optoelectronic device as claimed in claim 1, wherein the potting compound comprises a reflector section for reflecting light emitted by the diode.

10. A method for producing an optoelectronic device comprising:
providing a printed circuit board;
arranging a light source onto a surface of the printed circuit board, wherein the light source comprises at least one luminous face formed by at least one light-emitting diode;
electrically connecting the light-emitting diode to the printed circuit board; and
molding a potting compound to at least partly enclose the light-emitting diode.

11. The method as claimed in claim 10, further comprising:
forming an anchoring structure on the printed circuit board to anchor the potting compound on the printed circuit board (101) before said molding, such that during said molding the potting compound is anchored onto the printed circuit board by means of the anchoring structure.

12. The method as claimed in claim 11, wherein the anchoring structure comprises at least one cutout which is formed on the printed circuit board, such that potting compound is received into the cutout during said molding.

13. The method as claimed in claim 10, further comprising:
forming a mounting face for mounting of a component by the potting compound during said molding, wherein the mounting face is parallel to the surface.

14. The method as claimed in claim 10, wherein during said molding a section of the surface is kept free of the potting compound, such that after said molding the surface comprises a potting-compound-free-section for mounting of a component.

15. The method as claimed in claim 13, wherein as component a lens mount is arranged onto the mounting face.

16. The method as claimed in claim 10, further comprising:
forming, during said molding, a reflector section by the Dotting compound to reflect light emitted by the diode.

17. The optoelectronic device as claimed in claim 7, wherein as component a lens mount is arranged on the potting-compound-free-section.

18. The method as claimed in claim 14, wherein as component a lens mount is arranged onto the potting-compound-free-section.
